(19) United States
(12) Patent Application Publication
(10) Pub. No.: US 2024/0105775 A1
(43) Pub. Date: Mar. 28, 2024

(54) SEMICONDUCTOR DEVICE STRUCTURE AND METHOD FOR FORMING THE SAME

(71) Applicant: Taiwan Semiconductor Manufacturing Company, Ltd., Hsinchu (TW)

(72) Inventors: Chung-Yu CHIANG, Yuanlin Township (TW); Hsiao-Han LIU, Gongguan Township (TW); Yuan-Hung TSENG, Hsinchu County (TW); Chih-Yung LIN, Hsinchu County (TW)

(73) Assignee: Taiwan Semiconductor Manufacturing Company, Ltd., Hsinchu (TW)

(21) Appl. No.: 18/166,730

(22) Filed: Feb. 9, 2023

Related U.S. Application Data
(60) Provisional application No. 63/410,360, filed on Sep. 27, 2022.

(51) Int. Cl. H01L 29/08; H01L 21/8234; H01L 29/66

(52) U.S. Cl. CPC H01L 29/0847; H01L 21/823418; H01L 21/823468; H01L 29/6656; H01L 29/66795

(57) ABSTRACT

A method for forming a semiconductor device structure is provided. The method includes forming a first source/drain structure and a second source/drain structure over and in a substrate. The method includes forming a first gate stack, a second gate stack, a third gate stack, and a fourth gate stack over the substrate. Each of the first gate stack or the second gate stack is wider than each of the third gate stack or the fourth gate stack. The method includes forming a first contact structure and a second contact structure over the first source/drain structure and the second source/drain structure respectively. A first average width of the first contact structure is substantially equal to a second average width of the second contact structure.

### PRIORITY CLAIM AND CROSS-REFERENCE

This application claims the benefit of U.S. Provisional Application No. 63/410,360, filed on Sep. 27, 2022, the entirety of which is incorporated by reference herein.

### BACKGROUND

The semiconductor integrated circuit (IC) industry has experienced rapid growth. Technological advances in IC materials and design have produced generations of ICs. Each generation has smaller and more complex circuits than the previous generation. However, these advances have increased the complexity of processing and manufacturing ICs.

In the course of IC evolution, functional density (i.e., the number of interconnected devices per chip area) has generally increased while geometric size (i.e., the smallest component (or line) that can be created using a fabrication process) has decreased. This scaling-down process generally provides benefits by increasing production efficiency and lowering associated costs.

However, since feature sizes continue to decrease, fabrication processes continue to become more difficult to perform. Therefore, it is a challenge to form reliable semiconductor devices at smaller and smaller sizes.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIGS. 1A-1K are cross-sectional views of various stages of a process for forming a semiconductor device structure, in accordance with some embodiments.

FIG. 1A-1 is a perspective view of the semiconductor device structure of FIG. 1A, in accordance with some embodiments.

FIG. 1K-1 is a perspective view of the semiconductor device structure of FIG. 1K, in accordance with some embodiments.

FIGS. 2A-2C are cross-sectional views of various stages of a process for forming a semiconductor device structure, in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Furthermore, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The term “substantially” in the description, such as in “substantially flat” or in “substantially coplanar”, etc., will be understood by the person skilled in the art. In some embodiments the adjective substantially may be removed. Where applicable, the term “substantially” may also include embodiments with “entirely”, “completely”, “all”, etc. The term “substantially” may be varied in different technologies and be in the deviation range understood by the skilled in the art. For example, the term “substantially” may also relate to 90% of what is specified or higher, such as 95% of what is specified or higher, especially 99% of what is specified or higher, including 100% of what is specified, though the present invention is not limited thereto. Furthermore, terms such as “substantially parallel” or “substantially perpendicular” may be interpreted as not to exclude insignificant deviation from the specified arrangement and may include for example deviations of up to 10°. The word “substantially” does not exclude “completely” e.g. a composition which is “substantially free” from Y may be completely free from Y.

The term “about” may be varied in different technologies and be in the deviation range understood by the skilled in the art. The term “about” in conjunction with a specific distance or size is to be interpreted so as not to exclude insignificant deviation from the specified distance or size. For example, the term “about” may include deviations of up to 10% of what is specified, though the present invention is not limited thereto. The term “about” in relation to a numerical value x may mean x±5 or 10% of what is specified, though the present invention is not limited thereto.

Some embodiments of the disclosure are described. Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

Embodiments of the disclosure form a semiconductor device structure with FinFETs. The fins may be patterned by any suitable method. For example, the fins may be patterned using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used to pattern the fins. Source/drain structure(s) may refer to a source or a drain, individually or collectively dependent upon the context.

The advanced lithography process, method, and materials described in the current disclosure can be used in many applications, including fin-type field effect transistors (FinFETs). For example, the fins may be patterned to produce a relatively close spacing between features, for which the above disclosure is well suited. In addition, spacers used in forming fins of FinFETs can be processed according to the above disclosure. Source/drain structure(s) may refer to a source or a drain, individually or collectively dependent upon the context.

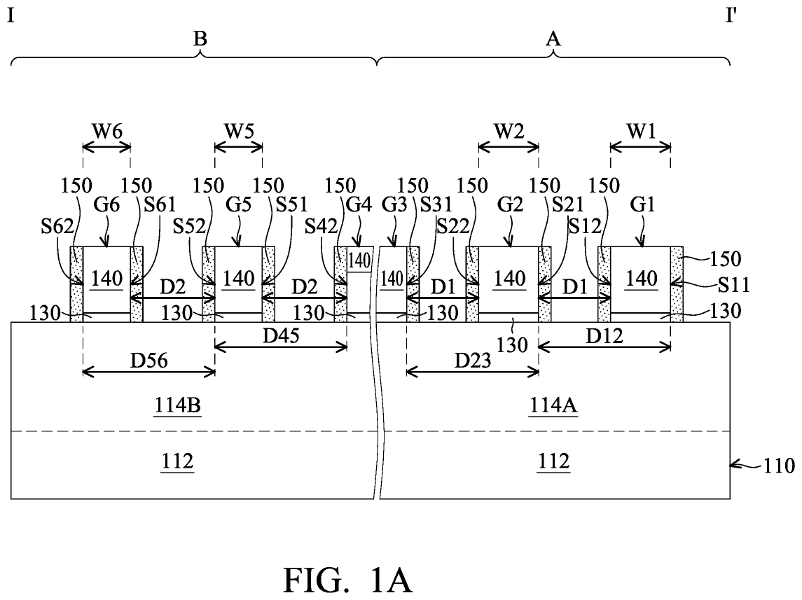

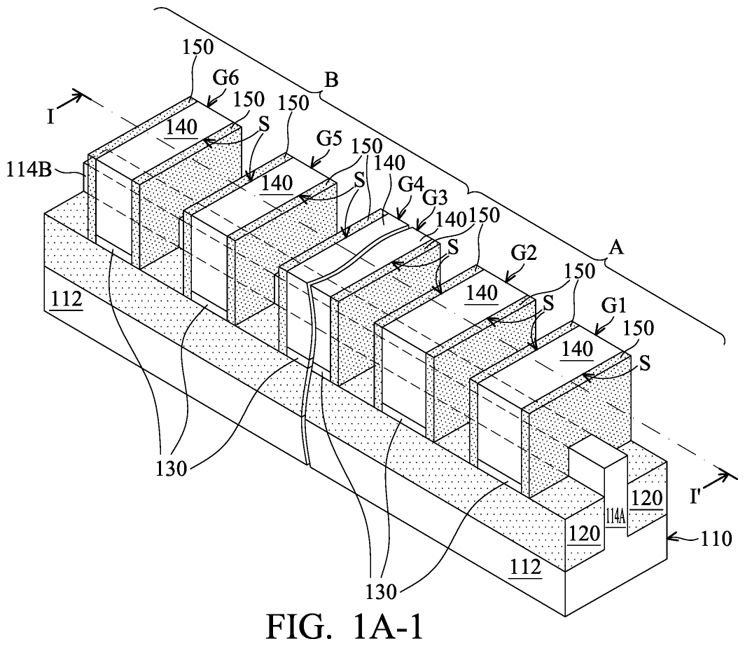

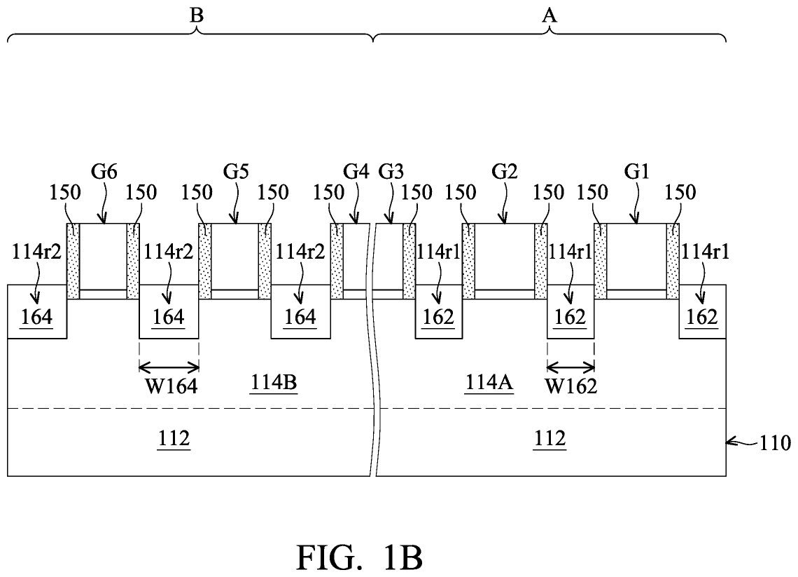

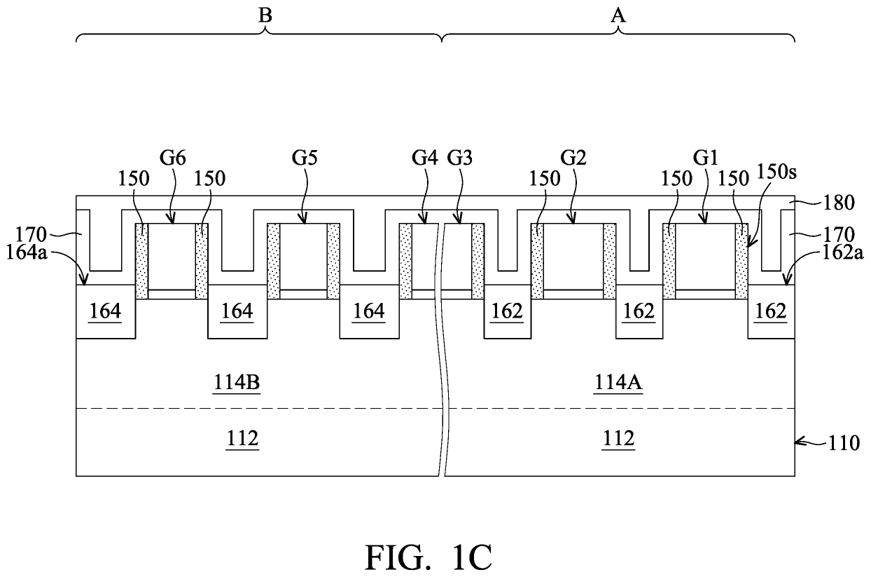

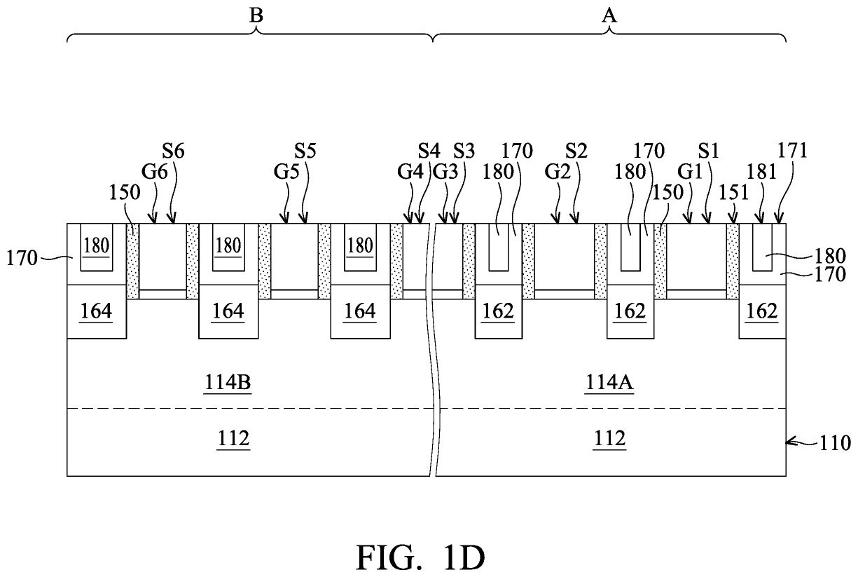

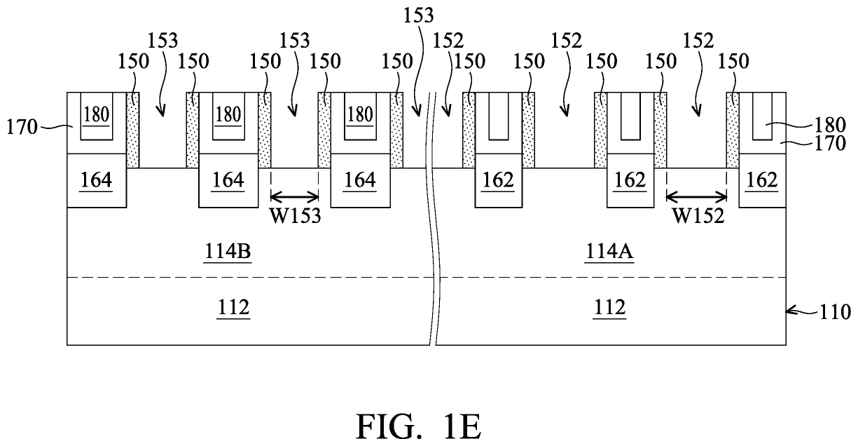

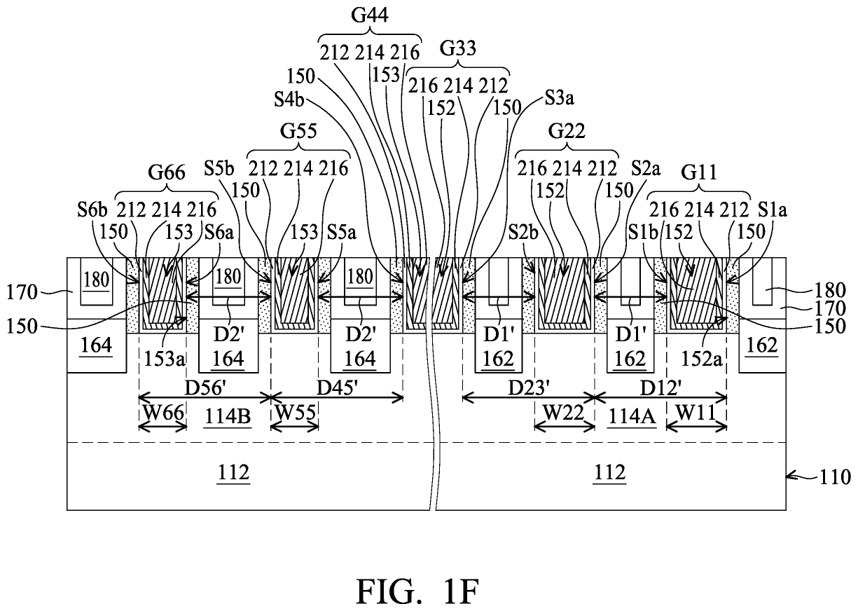

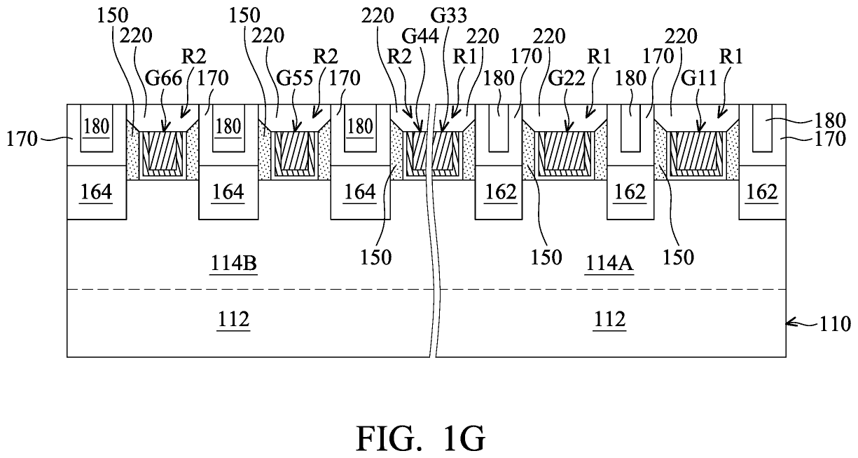

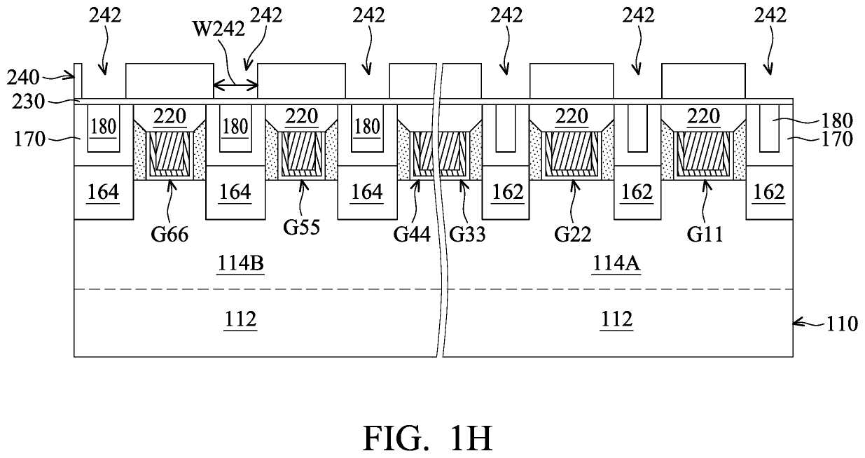

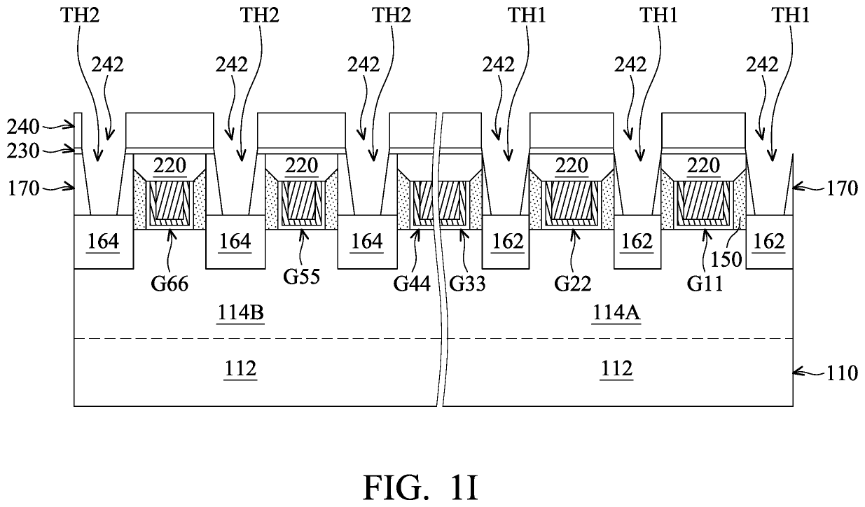

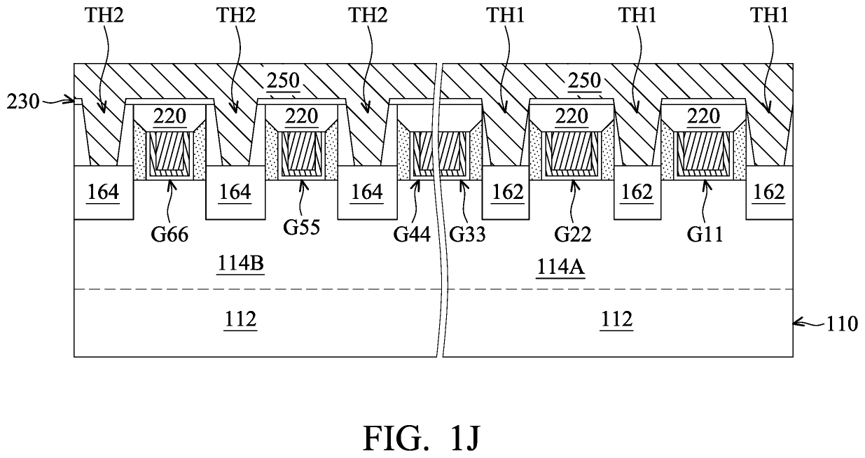

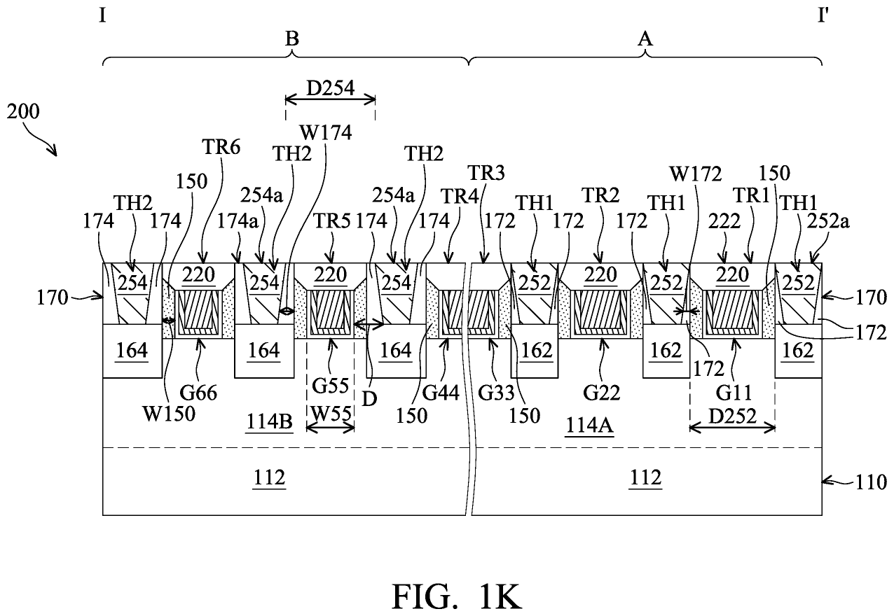

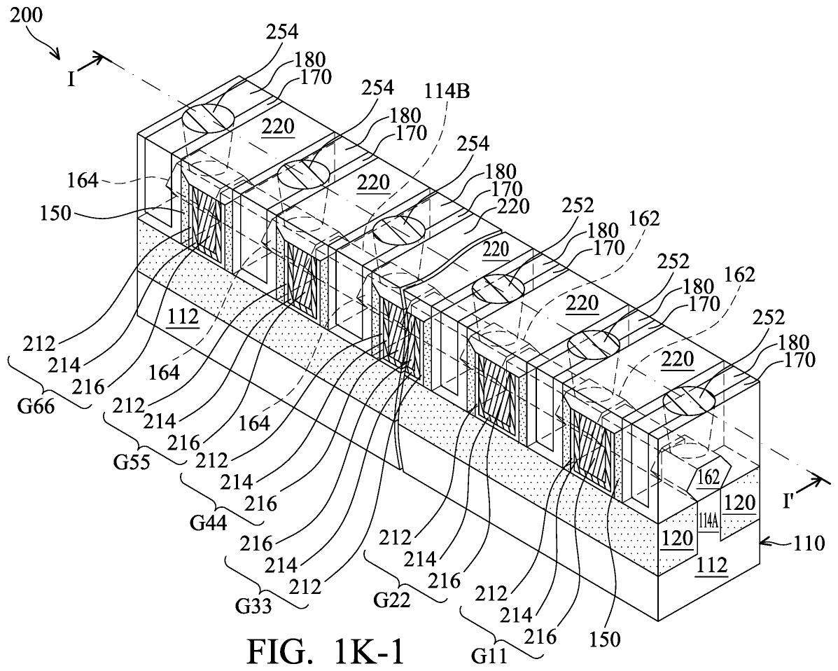

FIGS. 1A-1K are cross-sectional views of various stages of a process for forming a semiconductor device structure, in accordance with some embodiments. FIG. 1A-1 is a perspective view of the semiconductor device structure of FIG. 1A, in accordance with some embodiments. FIG. 1A is a cross-sectional view illustrating the semiconductor device structure along a sectional line I-I′ in FIG. 1A-1, in accordance with some embodiments.

As shown in FIGS. 1A and 1A-1, a substrate 110 is provided, in accordance with some embodiments. The substrate 110 has a wide gate region A and a narrow gate region B, in accordance with some embodiments. The substrate 110 has a base 112 and fins 114A and 114B, in accordance with some embodiments. The fins 114A and 114B are over the base 112, in accordance with some embodiments. The fins 114A and 114B are in the wide gate region A and the narrow gate region B respectively, in accordance with some embodiments.

The substrate 110 includes, for example, a semiconductor substrate. The substrate 110 includes, for example, a semiconductor wafer (such as a silicon wafer) or a portion of a semiconductor wafer. In some embodiments, the substrate 110 is made of an elementary semiconductor material including silicon or germanium in a single crystal structure, a polycrystal structure, or an amorphous structure.

In some other embodiments, the substrate 110 is made of a compound semiconductor, such as silicon carbide, gallium arsenide, gallium phosphide, indium phosphide, indium arsenide, an alloy semiconductor, such as SiGe or GaAsP, or a combination thereof. The substrate 110 may also include multi-layer semiconductors, semiconductor on insulator (SOI) (such as silicon on insulator or germanium on insulator), or a combination thereof.

In some embodiments, the substrate 110 is a device wafer that includes various device elements. In some embodiments, the various device elements are formed in and/or over the substrate 110. The device elements are not shown in figures for the purpose of simplicity and clarity. Examples of the various device elements include active devices, passive devices, other suitable elements, or a combination thereof. The active devices may include transistors or diodes (not shown) formed at a surface of the substrate 110. The passive devices include resistors, capacitors, or other suitable passive devices.

For example, the transistors may be metal oxide semiconductor field effect transistors (MOSFET), complementary metal oxide semiconductor (CMOS) transistors, bipolar junction transistors (BJT), high-voltage transistors, high-frequency transistors, p-channel and/or n-channel field effect transistors (PFETs/NFETs), etc.

Various processes, such as front-end-of-line (FEOL) semiconductor fabrication processes, are performed to form the various device elements. The FEOL semiconductor fabrication processes may include deposition, etching, implantation, photolithography, annealing, planarization, one or more other applicable processes, or a combination thereof.

In some embodiments, isolation features (not shown) are formed in the substrate 110. The isolation features are used to surround active regions and electrically isolate various device elements formed in and/or over the substrate 110 in the active regions. In some embodiments, the isolation features include shallow trench isolation (STI) features, local oxidation of silicon (LOCOS) features, other suitable isolation features, or a combination thereof.

As shown in FIGS. 1A and 1A-1, an isolation layer 120 is formed over the base 112, in accordance with some embodiments. Each of the fin 114A or 114B is partially in the isolation layer 120, in accordance with some embodiments. The isolation layer 120 includes oxide (such as silicon oxide), in accordance with some embodiments. The isolation layer 120 is formed by a chemical vapor deposition (CVD) process and an etching back process, in accordance with some embodiments.

As shown in FIGS. 1A and 1A-1, gate stacks G1, G2, and G3 are formed over and across the fin 114A, in accordance with some embodiments. The gate stacks G1, G2, and G3 are over the wide gate region A of the substrate 110, in accordance with some embodiments.

As shown in FIGS. 1A and 1A-1, gate stacks G4, G5, and G6 are formed over and across the fin 114B, in accordance with some embodiments. The gate stacks G4, G5, and G6 are over the narrow gate region B of the substrate 110, in accordance with some embodiments.

The width W1 of the gate stack G1 is substantially equal to the width W2 of the gate stack G2 or the width of the gate stack G3, in accordance with some embodiments. The width W5 of the gate stack G5 is substantially equal to the width W6 of the gate stack G6 or the width of the gate stack G4, in accordance with some embodiments.

Each of the gate stack G1, G2 or G3 is wider than each of the gate stack G4, G5 or G6, in accordance with some embodiments. That is, the width W1 of the gate stack G1, the width W2 of the gate stack G2 or the width of the gate stack G3 is greater than the width W5 of the gate stack G5, the width W6 of the gate stack G6 or the width of the gate stack G4, in accordance with some embodiments.

The gate stack G1 has opposite sidewalls S11 and S12, in accordance with some embodiments. The gate stack G2 has opposite sidewalls S21 and S22, in accordance with some embodiments. The gate stack G3 has opposite sidewalls S31, in accordance with some embodiments. The gate stack G4 has opposite sidewalls S42, in accordance with some embodiments. The gate stack G5 has opposite sidewalls S51 and S52, in accordance with some embodiments. The gate stack G6 has opposite sidewalls S61 and S62, in accordance with some embodiments.

The sidewall S11 faces away from the gate stack G2, in accordance with some embodiments. The sidewall S21 faces the gate stack G1, in accordance with some embodiments. The sidewall S52 faces the gate stack G6, in accordance with some embodiments. The sidewall S62 faces away from the gate stack G5, in accordance with some embodiments.

In some embodiments, a distance D12 is between the sidewalls S11 and S21. In some embodiments, a distance D23 is between the sidewalls S21 and S31. In some embodiments, a distance D45 is between the sidewalls S42 and S52. In some embodiments, a distance D56 is between the sidewalls S52 and S62. The distances D12, D23, D45 and D56 are substantially equal to each other, in accordance with some embodiments. The distance D12, D23, D45 or D56 ranges from about 30 nm to about 55 nm, in accordance with some embodiments.

The gate stacks G1, G2 and G3 are spaced apart from each other by a distance D1, in accordance with some embodiments. The gate stacks G4, G5 and G6 are spaced apart from each other by a distance D2, in accordance with some embodiments. The distances D1 and D2 are substantially equal to each other, in accordance with some embodiments.

Each of the gate stack G1, G2, G3, G4, G5, or G6 has a gate dielectric layer 130 and a gate electrode 140, in accordance with some embodiments. The gate electrode 140 is over the gate dielectric layer 130, in accordance with some embodiments.

The gate dielectric layer 130 is positioned between the gate electrode 140 and the fin 114A or 114B, in accordance with some embodiments. The gate dielectric layer 130 is also positioned between the gate electrode 140 and the isolation layer 120, in accordance with some embodiments.

The gate dielectric layer 130 is made of oxides such as silicon oxide, in accordance with some embodiments. The gate dielectric layer 130 is formed using a chemical vapor deposition process (CVD process) and an etching process, in accordance with some embodiments. The gate electrode 140 is made of a semiconductor material such as polysilicon, in accordance with some embodiments. The gate electrode 140 is formed using a chemical vapor deposition process and an etching process, in accordance with some embodiments.

As shown in FIGS. 1A and 1A-1, a spacer layer 150 is formed over sidewalls S11, S12, S21, S22, S31, S42, S51, S52, S61 and S62 of the gate stacks G1, G2, G3, G4, G5, and G6, in accordance with some embodiments. The spacer layer 150 surrounds the gate stacks G1, G2, G3, G4, G5, and G6, in accordance with some embodiments. The spacer layer 150 is positioned over the fins 114A and 114B and the isolation layer 120, in accordance with some embodiments.

The spacer layer 150 includes insulating materials, such as silicon oxide, silicon nitride, silicon oxynitride, or silicon carbide, in accordance with some embodiments. The formation of the spacer layer 150 includes a deposition process and an anisotropic etching process, in accordance with some embodiments.

As shown in FIG. 1B, portions of the fins 114A and 114B, which are not covered by the gate stacks G1, G2, G3, G4, G5, and G6 and the spacer layer 150, are removed, in accordance with some embodiments. The removal process forms recesses 114r1 and 114r2 in the fins 114A and 114B respectively, in accordance with some embodiments. The removal process includes an etching process such as a dry etching process, in accordance with some embodiments.

As shown in FIG. 1B, source/drain structures 162 are formed in the recesses 114r1 of the fin 114A, in accordance with some embodiments. The source/drain structures 162 are in direct contact with the fin 114A, in accordance with some embodiments. The source/drain structures 162 are positioned on two opposite sides of each of the gate stack G1, G2, or G3, in accordance with some embodiments. The source/drain structures 162 are between the gate stacks G1, G2, and G3, in accordance with some embodiments.

As shown in FIG. 1B, source/drain structures 164 are formed in the recesses 114r2 of the fin 114B, in accordance with some embodiments. The source/drain structures 164 are in direct contact with the fin 114B, in accordance with some embodiments.

The source/drain structures 164 are positioned on two opposite sides of each of the gate stack G4, G5, or G6, in accordance with some embodiments. The source/drain structures 164 are between the gate stacks G4, G5, and G6, in accordance with some embodiments.

Each source/drain structure 162 is narrower than each source/drain structure 164, in accordance with some embodiments. That is, the width W162 of the source/drain structure 162 is less than the width W164 of the source/drain structure 164, in accordance with some embodiments.

The source/drain structures 162 and/or 164 are made of an N-type conductivity material, in accordance with some embodiments. The N-type conductivity material includes silicon phosphorus (SiP) or another suitable N-type conductivity material. The source/drain structures 162 and 164 are formed using an epitaxial process, in accordance with some embodiments.

The source/drain structures 162 and/or 164 are doped with the Group VA element, in accordance with some embodiments. The Group VA element includes phosphor (P), antimony (Sb), or another suitable Group VA material. In some embodiments, a concentration of the Group VA element (e.g. phosphor) ranges from about 3E21 atoms/cm³ to about 7E21 atoms/cm³. The source/drain structures 162 and 164 are also referred to as doped structures, in accordance with some embodiments.

In some other embodiments, the source/drain structures 162 and/or 164 are made of a P-type conductivity material, in accordance with some embodiments. The P-type conductivity material includes silicon germanium (SiGe) or another suitable P-type conductivity material.

The source/drain structures 162 and 164 are formed using an epitaxial process, in accordance with some embodiments. The source/drain structures 162 and/or 164 are doped with the Group IIIA element, in accordance with some embodiments. The Group IIIA element includes boron or another suitable material.

As shown in FIG. 1C, an etch stop layer 170 is conformally formed over the gate stacks G1, G2, G3, G4, G5, and G6, the spacer layer 150, the isolation layer 120 (of FIG. 1A-1), and the source/drain structures 162 and 164, in accordance with some embodiments. The etch stop layer 170 conformally covers sidewalls 150s of the spacer layer 150 and top surfaces 162a and 164a of the source/drain structures 162 and 164, in accordance with some embodiments.

The etch stop layer 170 is made of an insulating material, such as a nitrogen-containing material (e.g., silicon nitride), in accordance with some embodiments. The etch stop layer 170 is formed using a deposition process, such as a chemical vapor deposition (CVD) process, an atomic layer deposition (ALD) process, or a physical vapor deposition (PVD) process, in accordance with some embodiments.

As shown in FIG. 1C, a dielectric layer 180 is formed over the etch stop layer 170, in accordance with some embodiments. The dielectric layer 180 is made of any suitable insulating material, such as silicon oxide, silicon oxynitride, borosilicate glass (BSG), phosphoric silicate glass (PSG), borophosphosilicate glass (BPSG), fluorinated silicate glass (FSG), a low-k material, a porous dielectric material, or a combination thereof.

The dielectric layer 180 is formed by a deposition process, such as a chemical vapor deposition (CVD) process, an atomic layer deposition (ALD) process, or a physical vapor deposition (PVD) process, in accordance with some embodiments.

As shown in FIG. 1D, a planarization process is then performed on the dielectric layer 180 and the etch stop layer 170 until top surfaces S1, S2, S3, S4, S5, and S6 of the gate stacks G1, G2, G3, G4, G5, and G6 are exposed, in accordance with some embodiments.

After the planarization process, the top surfaces S1, S2, S3, S4, S5, S6, 151, 171, and 181 of the gate stacks G1, G2, G3, G4, G5, and G6, the spacer layer 150, the etch stop layer 170, and the dielectric layer 180 are substantially level with each other, in accordance with some embodiments. The planarization process includes a chemical mechanical polishing (CMP) process, in accordance with some embodiments.

As shown in FIG. 1E, the gate stacks G1, G2, G3, G4, G5, and G6 are removed, in accordance with some embodiments. The removal process includes a wet etching process, in accordance with some embodiments. After the removal process, trenches 152 and 153 are formed in the spacer layer 150, in accordance with some embodiments. The trenches 152 expose portions of the fin 114A, in accordance with some embodiments. The trenches 153 expose portions of the fin 114B, in accordance with some embodiments.

Each trench 152 is wider than each trench 153, in accordance with some embodiments. That is, the width W152 of the trench 152 is greater than the width W153 of the trench 153, in accordance with some embodiments. The source/drain structures 162 are between the trenches 152, in accordance with some embodiments. The source/drain structures 164 are between the trenches 153, in accordance with some embodiments.

As shown in FIG. 1F, gate stacks G11, G22, and G33 are formed in the trenches 152 of the spacer layer 150, in accordance with some embodiments. As shown in FIG. 1F, gate stacks G44, G55, and G66 are formed in the trenches 153 of the spacer layer 150, in accordance with some embodiments.

Each of the gate stack G11, G22 or G33 is wider than each of the gate stack G44, G55 or G66, in accordance with some embodiments. In some embodiments, a distance D1′ between the gate stacks G11 and G22 or between the gate stacks G22 and G33 is less than a distance D2′ between the gate stacks G44 and G55 or between the gate stacks G55 and G66.

The gate stack G11 has opposite sidewalls S1a and S1b, in accordance with some embodiments. The gate stack G22 has opposite sidewalls S2a and S2b, in accordance with some embodiments. The gate stack G33 has opposite sidewalls S3a, in accordance with some embodiments. The gate stack G44 has opposite sidewalls S4b, in accordance with some embodiments. The gate stack G55 has opposite sidewalls S5a and S5b, in accordance with some embodiments. The gate stack G66 has opposite sidewalls S6a and S6b, in accordance with some embodiments.

The sidewall Sla faces away from the gate stack G22, in accordance with some embodiments. The sidewall S2a faces the gate stack G11, in accordance with some embodiments. The sidewall S5b faces the gate stack G66, in accordance with some embodiments. The sidewall S6b faces away from the gate stack G55, in accordance with some embodiments.

In some embodiments, a distance D12′ is between the sidewalls Sla and S2a. In some embodiments, a distance D23′ is between the sidewalls S2a and S3a. In some embodiments, a distance D45′ is between the sidewalls S4b and S5b. In some embodiments, a distance D56′ is between the sidewalls S5b and S6b.

The distances D12′, D23′, D45′ and D56′ are substantially equal to each other, in accordance with some embodiments. The distance D12′, D23′, D45′ or D56′ ranges from about 30 nm to about 55 nm, in accordance with some embodiments. As shown in FIGS. 1A and 1F, the distances D12, D12′, D23, D23′, D45, D45′, D56 and D56′ are substantially equal to each other, in accordance with some embodiments. The distances D12, D12′, D23, D23′, D45, D45′, D56 and D56′ are also referred to as pitches, in accordance with some embodiments.

The gate stacks G11, G22 and G33 are spaced apart from each other by a distance D1′, in accordance with some embodiments. The gate stacks G44, G55 and G66 are spaced apart from each other by a distance D2′, in accordance with some embodiments. The distances D1′ and D2′ are substantially equal to each other, in accordance with some embodiments. As shown in FIGS. 1A and 1F, the distances D1, D1′, D2 and D2′ are substantially equal to each other, in accordance with some embodiments.

The width W11 of the gate stack G11 is substantially equal to the width W22 of the gate stack G22 or the width of the gate stack G33, in accordance with some embodiments. The width W55 of the gate stack G55 is substantially equal to the width W66 of the gate stack G66 or the width of the gate stack G44, in accordance with some embodiments.

The source/drain structures 162 are between the gate stacks G11, G22 and G33, in accordance with some embodiments. The source/drain structures 164 are between the gate stacks G44, G55 and G66, in accordance with some embodiments. Each of the gate stack G11, G22 or G33 is wider than each of the gate stack G44, G55 or G66, in accordance with some embodiments.

As shown in FIG. 1F, each of the gate stack G11, G22, G33, G44, G55, or G66 includes a gate dielectric layer 212, a work function metal layer 214, and a gate electrode 216, in accordance with some embodiments. The gate dielectric layer 212 conformally covers the inner walls 152a and 153a of the trenches 152 and 153 and the fins 114A and 114B exposed by the trenches 152 and 153, in accordance with some embodiments.

The work function metal layer 214 is formed over the gate dielectric layer 212, in accordance with some embodiments. The work function metal layer 214 conformally covers the gate dielectric layer 212, in accordance with some embodiments. The gate electrode 216 is formed over the work function metal layer 214 to fill the trench 152 or 153, in accordance with some embodiments.

The gate dielectric layer 212 is made of an insulating material such as silicon oxide, silicon nitride, silicon oxynitride, a dielectric material with high dielectric constant (high-K), another suitable dielectric material, or a combination thereof.

Examples of high-K dielectric materials include hafnium oxide, zirconium oxide, aluminum oxide, hafnium dioxide-alumina alloy, hafnium silicon oxide, hafnium silicon oxynitride, hafnium tantalum oxide, hafnium titanium oxide, hafnium zirconium oxide, another suitable high-K material, or a combination thereof.

The gate dielectric layer 212 is formed using a deposition process and a planarization process, in accordance with some embodiments. The deposition process includes a physical vapor deposition (PVD) process, a CVD process, an atomic layer deposition (ALD), another suitable method, or a combination thereof.

The work function metal layer 214 provides a desired work function for transistors to enhance device performance including improved threshold voltage. In the embodiments of forming an NMOS transistor, the work function metal layer 214 can be an n-type metal capable of providing a work function value suitable for the device, such as equal to or less than about 4.5 eV. The n-type metal may be made of metal, metal carbide, metal nitride, or a combination thereof. For example, the n-type metal is made of tantalum, tantalum nitride, or a combination thereof.

In the embodiments of forming a PMOS transistor, the work function metal layer 214 can be a p-type metal capable of providing a work function value suitable for the device, such as equal to or greater than about 4.8 eV. The p-type metal may be made of metal, metal carbide, metal nitride, other suitable materials, or a combination thereof.

For example, the p-type metal is made of titanium, titanium nitride, other suitable materials, or a combination thereof. The work function metal layer 214 is formed using a deposition process and a planarization process, in accordance with some embodiments. The deposition process includes a physical vapor deposition (PVD) process, a CVD process, an atomic layer deposition (ALD), a plating process, another suitable method, or a combination thereof.

In some embodiments, the work function metal layers 214 of the gate stacks G11, G22, G33, G44, G55, and G66 are made of the same material. The work function metal layers 214 of the gate stacks G11, G22, G33, G44, G55, and G66 are formed in the same deposition process, in accordance with some embodiments.

In some other embodiments, the work function metal layers 214 of the gate stacks G11, G22, and G33 and the work function metal layers 214 of the gate stacks G44, G55, and G66 are made of different materials. The work function metal layers 214 of the gate stacks G11, G22, and G33 and the work function metal layers 214 of the gate stacks G44, G55, and G66 are formed individually, in accordance with some embodiments.

For example, during the formation of the work function metal layers 214 of the gate stacks G11, G22, and G33, the trenches 153 are covered by a first mask layer (not shown), and during the formation of the work function metal layers 214 of the gate stacks G44, G55, and G66, the trenches 152 are covered by a second mask layer (not shown).

The gate electrode 216 is made of a suitable metal material, such as aluminum, tungsten, gold, platinum, cobalt, another suitable metal, an alloy thereof, or a combination thereof, in accordance with some embodiments. The gate electrode 216 is formed using a deposition process and a planarization process, in accordance with some embodiments. The deposition process includes a physical vapor deposition (PVD) process, a CVD process, an atomic layer deposition (ALD), a plating process, another suitable method, or a combination thereof.

As shown in FIG. 1G, upper portions of the gate stacks G11, G22, G33, G44, G55, and G66 are removed, in accordance with some embodiments. After the removal process, recesses R1 and R2 are formed in the spacer layer 150 and the etch stop layer 170, in accordance with some embodiments. The removal process of the upper portions of the gate stacks G11, G22, G33, G44, G55, and G66 includes a wet etching process or a dry etching process, in accordance with some embodiments.

As shown in FIG. 1G, a cap layer 220 is formed in the recesses R1 and R2, in accordance with some embodiments. The cap layer 220 is made of a dielectric material, such as silicon nitride, in accordance with some embodiments. The cap layer 220 is formed using a deposition process and a chemical mechanical polishing process, in accordance with some embodiments.

As shown in FIG. 1H, a protective layer 230 is formed over the etch stop layer 170, the dielectric layer 180, and the cap layer 220, in accordance with some embodiments. The protective layer 230 is configured to protect the etch stop layer 170, the dielectric layer 180, and the cap layer 220 from being damaged during a subsequent process, in accordance with some embodiments.

The protective layer 230 is made of silicon nitride, a plasma-enhanced oxide (PEOX), or another suitable material, in accordance with some embodiments. The protective layer 230 is formed using a deposition process such as a physical vapor deposition (PVD) process, a chemical vapor deposition (CVD) process, an atomic layer deposition (ALD), or a combination thereof, in accordance with some embodiments.

As shown in FIG. 1H, a mask layer 240 is formed over the protective layer 230, in accordance with some embodiments. The mask layer 240 is made of a polymer material such as a photoresist material, in accordance with some embodiments.

As shown in FIG. 1H, portions of the mask layer 240 are removed to form openings 242 in the mask layer 240, in accordance with some embodiments. The openings 242 expose portions of the protective layer 230, in accordance with some embodiments.

The openings 242 have the same width W242, in accordance with some embodiments. The portions of the mask layer 240 are removed using a photolithography process, in accordance with some embodiments. The photolithography process includes an EUV lithography process, in accordance with some embodiments.

As shown in FIGS. 1H and 11, portions of the protective layer 230, the dielectric layer 180, and the etch stop layer 170 are removed through the openings 242 to form through holes TH1 and TH2 passing through the protective layer 230, the etch stop layer 170 and the dielectric layer 180, in accordance with some embodiments.

The through holes TH1 expose the source/drain structures 162, in accordance with some embodiments. The through holes TH2 expose the source/drain structures 164, in accordance with some embodiments. The through holes TH1 and TH2 have the same average width, in accordance with some embodiments. The removal process includes an etching process such as a dry etching process, in accordance with some embodiments.

As shown in FIG. 1J, the mask layer 240 is removed, in accordance with some embodiments. As shown in FIG. 1J, a conductive layer 250 is formed over the protective layer 230 and in the through holes TH1 and TH2, in accordance with some embodiments. The conductive layer 250 is made of tungsten (W), aluminum (Al), gold (Au), silver (Ag), a combination thereof, an alloy thereof, or another suitable conductive material. The conductive layer 250 is formed using a physical vapor deposition process, a chemical vapor deposition process, or another suitable process.

FIG. 1K-1 is a perspective view of the semiconductor device structure of FIG. 1K, in accordance with some embodiments. FIG. 1K is a cross-sectional view illustrating the semiconductor device structure along a sectional line I-I′ in FIG. 1K-1, in accordance with some embodiments.

As shown in FIGS. 1K and 1K-1, a planarization process is performed until the top surface 222 of the cap layer 220 is exposed, in accordance with some embodiments. In this step, a semiconductor device structure 200 is substantially formed, in accordance with some embodiments.

The planarization process removes the protective layer 230 and an upper portion of the conductive layer 250, in accordance with some embodiments. The conductive layer 250 remaining in each through hole TH1 forms a contact structure 252, in accordance with some embodiments. The conductive layer 250 remaining in each through hole TH2 forms a contact structure 254, in accordance with some embodiments.

The contact structures 252 and 254 pass through the etch stop layer 170 and the dielectric layer 180, in accordance with some embodiments. The contact structures 252 are electrically connected to the source/drain structures 162 thereunder, in accordance with some embodiments. The contact structures 254 are electrically connected to the source/drain structures 164 thereunder, in accordance with some embodiments.

The gate stacks G11, G22 and G33 are between the contact structures 252, in accordance with some embodiments. The gate stacks G44, G55 and G66 are between the contact structures 254, in accordance with some embodiments. In some embodiments, an average width of the contact structure 252 is substantially equal to an average width of the contact structure 254.

The contact structures 252 are spaced apart from each other by a distance D252, in accordance with some embodiments. The contact structures 254 are spaced apart from each other by a distance D254, in accordance with some embodiments. The distance D252 is substantially equal to the distance D254, in accordance with some embodiments.

As shown in FIG. 1K, the etch stop layer 170 has thin portions 172 and thick portions 174, in accordance with some embodiments. Each thin portion 172 is thinner than each thick portion 174, in accordance with some embodiments. The thin portions 172 are between the contact structures 252 and the spacer layer 150, in accordance with some embodiments. The thin portions 172 are between the contact structures 252 and the gate stacks G11, G22, and G33, in accordance with some embodiments.

In some embodiments, top parts of the thin portions 172 are between the contact structures 252 and the cap layer 220. As shown in FIG. 1K, a width W172 of the thin portion 172 increases toward the source/drain structure 162, in accordance with some embodiments. As shown in FIG. 1K, the thin portion 172 has a triangular shape, in accordance with some embodiments.

The thick portions 174 are between the contact structures 254 and the spacer layer 150, in accordance with some embodiments. The thick portions 174 are between the contact structures 254 and the gate stacks G44, G55, and G66, in accordance with some embodiments.

In some embodiments, top parts of the thick portions 174 are between the contact structures 254 and the cap layer 220. As shown in FIG. 1K, the thick portion 174 has a trapezoidal shape, in accordance with some embodiments. In some embodiments, a width W174 of the thick portion 174 increases toward the source/drain structure 164.

After the planarization process, the top surfaces 222, 252a, 254a, and 174a of the cap layer 220, the contact structures 252 and 254, and the thick portion 174 of the etch stop layer 170 are substantially level with each other, in accordance with some embodiments. The planarization process includes a chemical mechanical polishing process, in accordance with some embodiments.

The width W150 of the spacer layer 150 ranges from about 1 nm to about 10 nm, in accordance with some embodiments. The contact structure 254 is spaced apart from the gate stack G55 by a distance D, in accordance with some embodiments. In some embodiments, a ratio of the distance D to the width W55 of the gate stack G55 ranges from about 0.3 to about 0.8.

The gate stack G11 and the corresponding source/drain structures 162 together form a transistor TR1, in accordance with some embodiments. The gate stack G22 and the corresponding source/drain structures 162 together form a transistor TR2, in accordance with some embodiments. The gate stack G33 and the corresponding source/drain structures 162 together form a transistor TR3, in accordance with some embodiments. The transistors TR1, TR2 and TR3 include low power transistors with low leakage current, in accordance with some embodiments.

The gate stack G44 and the corresponding source/drain structures 164 together form a transistor TR4, in accordance with some embodiments. The gate stack G55 and the corresponding source/drain structures 164 together form a transistor TR5, in accordance with some embodiments. The gate stack G66 and the corresponding source/drain structures 164 together form a transistor TR6, in accordance with some embodiments. The transistors TR4, TR5 and TR6 include high speed transistors, in accordance with some embodiments. The high speed transistors may be used in high performance computing (HPC) devices.

The method of the application forms the contact structures 252 and 254 over the wide gate region A and the narrow gate region B respectively, the contact structures 252 and 254 have the same width, and the gate stacks over the wide gate region A and the narrow gate region B have the same pitch, in accordance with some embodiments. Therefore, the method is able to adjust the width of the gate stack according to requirements and maintain the width of the contact structures, in accordance with some embodiments. Therefore, the performance of the semiconductor device structure 200 is improved, in accordance with some embodiments.

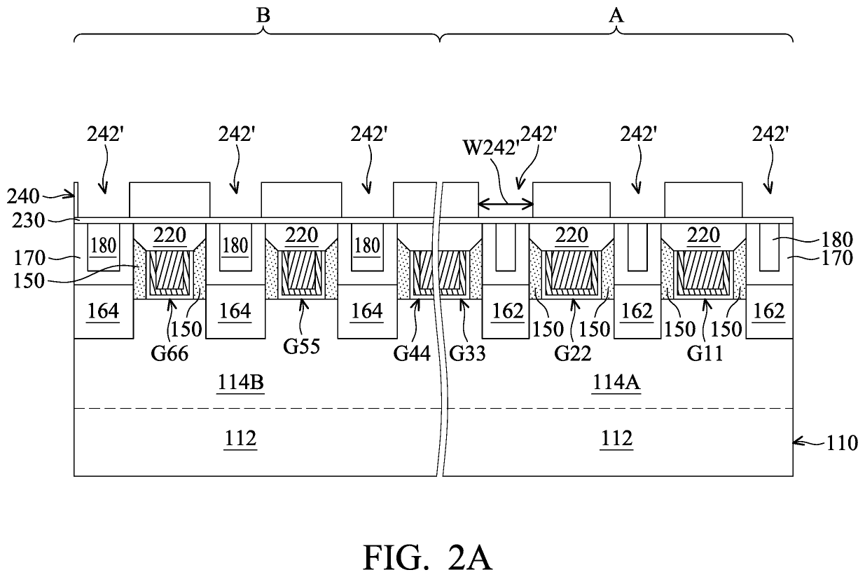

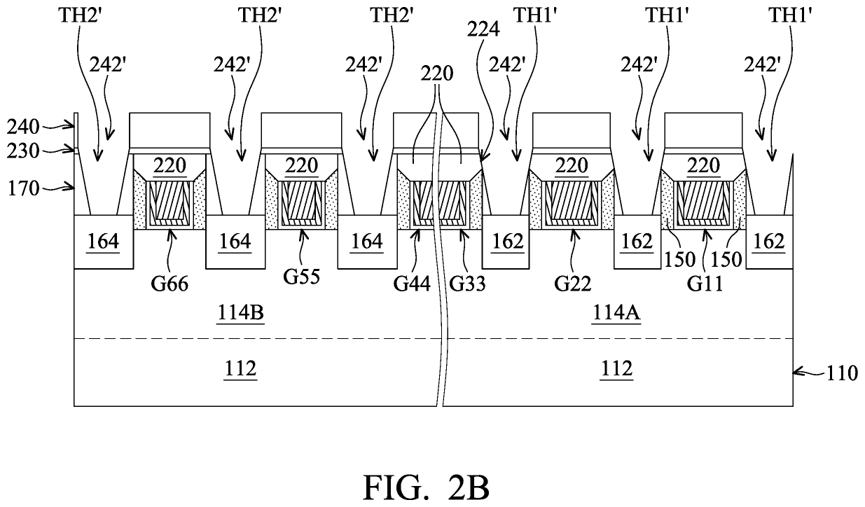

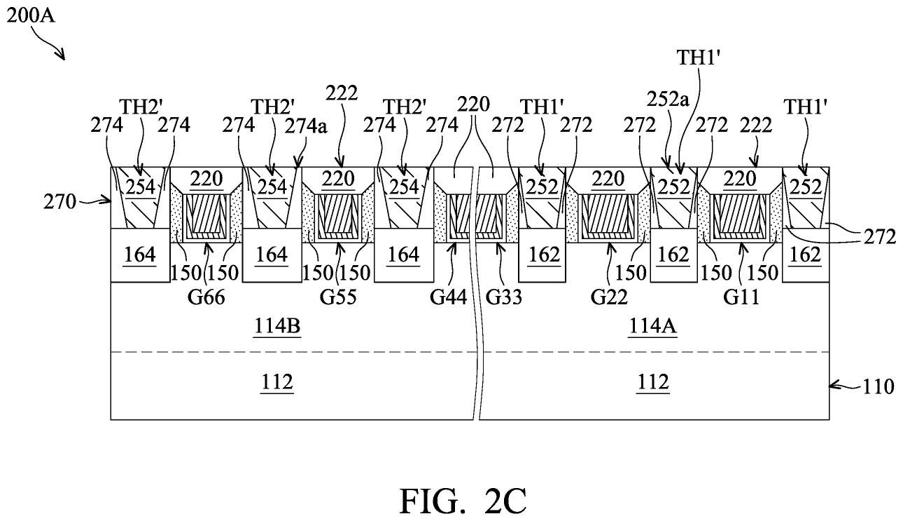

FIGS. 2A-2C are cross-sectional views of various stages of a process for forming a semiconductor device structure, in accordance with some embodiments. As shown in FIG. 2A, the steps of FIGS. 1A-1G are performed, in accordance with some embodiments. As shown in FIG. 2A, a protective layer 230 is formed over the etch stop layer 170, the dielectric layer 180, and the cap layer 220, in accordance with some embodiments.

As shown in FIG. 2A, a mask layer 240 is formed over the protective layer 230, in accordance with some embodiments. As shown in FIG. 2A, portions of the mask layer 240 are removed to form openings 242′ in the mask layer 240, in accordance with some embodiments.

The opening 242′ is wider than the opening 242 in FIG. 1H, in accordance with some embodiments. That is, the width W242′ of the opening 242′ is greater than the width W242 of the opening 242 in FIG. 1H, in accordance with some embodiments. The opening 242′ partially overlaps the cap layer 220, in accordance with some embodiments.

As shown in FIGS. 2A and 2B, portions of the cap layer 220, the protective layer 230, the dielectric layer 180, and the etch stop layer 170 are removed through the openings 242′ to form through holes TH1′ and TH2′ passing through the cap layer 220, the protective layer 230, the etch stop layer 170 and the dielectric layer 180, in accordance with some embodiments. The through holes TH1′ expose sidewalls 224 of the cap layer 220, in accordance with some embodiments.

As shown in FIG. 2C, the steps of FIGS. 1J-1K are performed to from the contact structures 252 and 254 in the through holes TH1′ and TH2′ respectively, in accordance with some embodiments. In some embodiments, a portion of the contact structure 252 is over the spacer layer 150. That is, the contact structure 252 overlaps the spacer layer 150, in accordance with some embodiments.

The contact structure 252 is in direct contact with the spacer layer 150 surrounding the gate stacks G11, G22 and G33, in accordance with some embodiments. In this step, a semiconductor device structure 200A is substantially formed, in accordance with some embodiments.

Processes and materials for forming the semiconductor device structure 200A may be similar to, or the same as, those for forming the semiconductor device structure 200 described above. Elements designated by the same or similar reference numbers as those in FIGS. 1A to 2C have the same or similar structures and the materials. Therefore, the detailed descriptions thereof will not be repeated herein.

In accordance with some embodiments, semiconductor device structures and methods for forming the same are provided. The methods (for forming the semiconductor device structure) form contact structures over a wide gate region and a narrow gate region respectively, the contact structures have the same width, and wide gate stacks over the wide gate region and narrow gate stacks over the narrow gate region have the same pitch. Therefore, the method is able to adjust the widths of the gate stacks according to requirements and maintain the widths of the contact structures. Therefore, the performance of the semiconductor device structure is improved. The wide gate stack is used to form, for example, a low power transistor with low leakage current. The narrow gate stack is used to form, for example, a high speed transistor.

In accordance with some embodiments, a method for forming a semiconductor device structure is provided. The method includes forming a first source/drain structure and a second source/drain structure over and in a substrate. The method includes forming a first gate stack, a second gate stack, a third gate stack, and a fourth gate stack over the substrate. The first source/drain structure is between the first gate stack and the second gate stack, the second source/drain structure is between the third gate stack and the fourth gate stack, each of the first gate stack or the second gate stack is wider than each of the third gate stack or the fourth gate stack. The first gate stack has a first sidewall facing away from the second gate stack, the second gate stack has a second sidewall facing the first gate stack, the third gate stack has a third sidewall facing the fourth gate stack, the fourth gate stack has a fourth sidewall facing away from the third gate stack, a first distance between the first sidewall and the second sidewall is substantially equal to a second distance between the third sidewall and the fourth sidewall. The method includes forming a first contact structure and a second contact structure over the first source/drain structure and the second source/drain structure respectively. A first average width of the first contact structure is substantially equal to a second average width of the second contact structure.

In accordance with some embodiments, a method for forming a semiconductor device structure is provided. The method includes forming a spacer layer over a substrate and having a first trench, a second trench, a third trench, and a fourth trench. Each of the first trench or the second trench is wider than each of the third trench or the fourth trench. The method includes forming a first source/drain structure and a second source/drain structure over and in a substrate. The first source/drain structure is between the first trench and the second trench, and the second source/drain structure is between the third trench and the fourth trench. The method includes forming an etch stop layer over sidewalls of the spacer layer and top surfaces of the first source/drain structure and the second source/drain structure. The method includes forming a first gate stack, a second gate stack, a third gate stack, and a fourth gate stack in the first trench, the second trench, the third trench, and the fourth trench respectively. The method includes forming a first contact structure and a second contact structure over the first source/drain structure and the second source/drain structure respectively and passing through the etch stop layer. A first average width of the first contact structure is substantially equal to a second average width of the second contact structure, and the etch stop layer between the first gate stack and the second gate stack is thinner than the etch stop layer between the third gate stack and the fourth gate stack.

In accordance with some embodiments, a semiconductor device structure is provided. The semiconductor device structure includes a substrate. The semiconductor device structure includes a first source/drain structure and a second source/drain structure over and in the substrate. The semiconductor device structure includes a first gate stack, a second gate stack, a third gate stack, and a fourth gate stack over the substrate. The first source/drain structure is between the first gate stack and the second gate stack, the second source/drain structure is between the third gate stack and the fourth gate stack, each of the first gate stack or the second gate stack is wider than each of the third gate stack or the fourth gate stack. The first gate stack has a first sidewall facing away from the second gate stack, the second gate stack has a second sidewall facing the first gate stack, the third gate stack has a third sidewall facing the fourth gate stack, the fourth gate stack has a fourth sidewall facing away from the third gate stack, a first distance between the first sidewall and the second sidewall is substantially equal to a second distance between the third sidewall and the fourth sidewall. The semiconductor device structure includes a first contact structure and a second contact structure over the first source/drain structure and the second source/drain structure respectively. A first average width of the first contact structure is substantially equal to a second average width of the second contact structure.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for forming a semiconductor device structure, comprising:
forming a first source/drain structure and a second source/drain structure over and in a substrate;
forming a first gate stack, a second gate stack, a third gate stack, and a fourth gate stack over the substrate, wherein the first source/drain structure is between the first gate stack and the second gate stack, the second source/drain structure is between the third gate stack and the fourth gate stack, each of the first gate stack or the second gate stack is wider than each of the third gate stack or the fourth gate stack,
the first gate stack has a first sidewall facing away from the second gate stack, the second gate stack has a second sidewall facing the first gate stack, the third gate stack has a third sidewall facing the fourth gate stack, the fourth gate stack has a fourth sidewall facing away from the third gate stack, and a first distance between the first sidewall and the second sidewall is substantially equal to a second distance between the third sidewall and the fourth sidewall; and
forming a first contact structure and a second contact structure over the first source/drain structure and the second source/drain structure respectively, wherein a first average width of the first contact structure is substantially equal to a second average width of the second contact structure.

2. The method for forming the semiconductor device structure as claimed in claim 1, wherein the first source/drain structure is narrower than the second source/drain structure.

3. The method for forming the semiconductor device structure as claimed in claim 1, wherein a third distance between the first gate stack and the second gate stack is less than a fourth distance between the third gate stack and the fourth gate stack.

4. The method for forming the semiconductor device structure as claimed in claim 1, further comprising:
forming a dielectric layer over the first source/drain structure and the second source/drain structure, wherein
the forming of the first contact structure and the second contact structure comprises:
partially removing the dielectric layer to form a first through hole and a second through hole in the dielectric layer, wherein the first through hole and the second through hole expose the first source/drain structure and the second source/drain structure respectively; and
forming the first contact structure and the second contact structure in the first through hole and the second through hole respectively.

5. The method for forming the semiconductor device structure as claimed in claim 4, further comprising:
forming an etch stop layer over the first source/drain structure before forming the dielectric layer over the first source/drain structure and the second source/drain structure, wherein the dielectric layer is formed over the etch stop layer, the partially removing of the dielectric layer further partially removes the etch stop layer, and the first through hole and the first contact structure further pass through the etch stop layer.

6. The method for forming the semiconductor device structure as claimed in claim 5, wherein the etch stop layer has a triangular shape in a cross-sectional view of the etch stop layer.

7. The method for forming the semiconductor device structure as claimed in claim 5, wherein the etch stop layer is further formed over the second source/drain structure, the partially removing of the dielectric layer further partially removes the etch stop layer over the second source/drain structure, and the second through hole and the second contact structure further pass through the etch stop layer.

8. The method for forming the semiconductor device structure as claimed in claim 7, wherein the etch stop layer over the second source/drain structure has a trapezoidal shape in a cross-sectional view of the etch stop layer.

9. The method for forming the semiconductor device structure as claimed in claim 5, further comprising:
before forming the first source/drain structure and the second source/drain structure over and in the substrate, forming a spacer layer over the substrate, wherein the spacer layer has a first trench, a second trench, a third trench, and a fourth trench, the first gate stack, the second gate stack, the third gate stack, and the fourth gate stack are formed in the first trench, the second trench, the third trench, and the fourth trench respectively, and the etch stop layer is formed over a sidewall of the spacer layer.

10. The method for forming the semiconductor device structure as claimed in claim 9, wherein the first contact structure is in direct contact with the spacer layer over the second sidewall of the second gate stack.

11. A method for forming a semiconductor device structure, comprising:
forming a spacer layer over a substrate and having a first trench, a second trench, a third trench, and a fourth trench, wherein each of the first trench or the second trench is wider than each of the third trench or the fourth trench;
forming a first source/drain structure and a second source/drain structure over and in a substrate, wherein the first source/drain structure is between the first trench and the second trench, and the second source/drain structure is between the third trench and the fourth trench;
forming an etch stop layer adjacent to the spacer layer and covering the first source/drain structure and the second source/drain structure;
forming a first gate stack, a second gate stack, a third gate stack, and a fourth gate stack in the first trench, the second trench, the third trench, and the fourth trench respectively; and
forming a first contact structure and a second contact structure over the first source/drain structure and the second source/drain structure respectively and passing through the etch stop layer, wherein a first average width of the first contact structure is substantially equal to a second average width of the second contact structure, and the etch stop layer between the first gate stack and the second gate stack is thinner than the etch stop layer between the third gate stack and the fourth gate stack.

12. The method for forming the semiconductor device structure as claimed in claim 11, wherein the first gate stack has a first sidewall facing away from the second gate stack, the second gate stack has a second sidewall facing the first gate stack, the third gate stack has a third sidewall facing the fourth gate stack, the fourth gate stack has a fourth sidewall facing away from the third gate stack, and a first distance between the first sidewall and the second sidewall is substantially equal to a second distance between the third sidewall and the fourth sidewall.

13. The method for forming the semiconductor device structure as claimed in claim 11, further comprising:
forming a third contact structure and a fourth contact structure over the substrate, wherein the first gate stack is between the first contact structure and the third contact structure, the fourth gate stack is between the second contact structure and the fourth contact structure, and a first distance between the first contact structure and the third contact structure is substantially equal to a second distance between the second contact structure and the fourth contact structure.

14. The method for forming the semiconductor device structure as claimed in claim 11, wherein a portion of the first contact structure is over the spacer layer.

15. The method for forming the semiconductor device structure as claimed in claim 14, wherein the etch stop layer between the first contact structure and the first gate stack has a triangular shape in a cross-sectional view of the etch stop layer, the first contact structure, and the first gate stack.

16. A semiconductor device structure, comprising:
a substrate;
a first source/drain structure and a second source/drain structure over and in the substrate;
a first gate stack, a second gate stack, a third gate stack, and a fourth gate stack over the substrate, wherein the first source/drain structure is between the first gate stack and the second gate stack, the second source/drain structure is between the third gate stack and the fourth gate stack, each of the first gate stack or the second gate stack is wider than each of the third gate stack or the fourth gate stack,
the first gate stack has a first sidewall facing away from the second gate stack, the second gate stack has a second sidewall facing the first gate stack, the third gate stack has a third sidewall facing the fourth gate stack, the fourth gate stack has a fourth sidewall facing away from the third gate stack, and a first distance between the first sidewall and the second sidewall is substantially equal to a second distance between the third sidewall and the fourth sidewall; and
a first contact structure and a second contact structure over the first source/drain structure and the second source/drain structure respectively, wherein a first average width of the first contact structure is substantially equal to a second average width of the second contact structure.

17. The semiconductor device structure as claimed in claim 16, further comprising:
an etch stop layer over the first source/drain structure, the second source/drain structure, the second sidewall of the second gate stack, and the third sidewall of the third gate stack, wherein the etch stop layer over the second sidewall is thinner than the etch stop layer over the third sidewall.

18. The semiconductor device structure as claimed in claim 16, wherein a width of the etch stop layer over the first source/drain structure increases toward the first source/drain structure.

19. The semiconductor device structure as claimed in claim 16, wherein the first source/drain structure is narrower than the second source/drain structure.

20. The semiconductor device structure as claimed in claim 16, further comprising:
a spacer layer surrounding the first gate stack and between the first gate stack and the etch stop layer, wherein the first contact structure is in direct contact with the spacer layer.
